(19) United States
(12) Patent Application Publication
(10) Pub. No.: US 2025/0069647 A1
(43) Pub. Date: Feb. 27, 2025

(54) SEMICONDUCTOR DEVICE HAVING ARRAY CONTROL CIRCUIT CONTROLLING SENSE AMPLIFIERS

(71) Applicant: MICRON TECHNOLOGY, INC., BOISE, ID (US)

(72) Inventors: Hirokazu Ato, Sagamihara (JP); Mamoru Nishizaki, Yokohama (JP)

(73) Assignee: MICRON TECHNOLOGY, INC., Boise, ID (US)

(21) Appl. No.: 18/749,464

(22) Filed: Jun. 20, 2024

Related U.S. Application Data
(60) Provisional application No. 63/578,242, filed on Aug. 23, 2023.

(51) Int. Cl. G11C 11/4091; G11C 11/408; G11C 11/4097

(52) U.S. Cl. CPC G11C 11/4091; G11C 11/4085; G11C 11/4097

(57) ABSTRACT

An example apparatus includes: first and second sense amplifier regions arranged such that the memory mat is sandwiched between the first and second sense amplifier regions in a first direction, the first and second sense amplifier regions including first and second sense amplifiers, respectively; and first and second array control circuit regions arranged in the first direction, the first and second array control circuit regions including first and second array control circuits configured to control the first and second sense amplifiers, respectively. Each of the first and second array control circuit regions includes a first well region in which a first circuit part of each of the first and second array control circuits are arranged, respectively. The first well region of the first array control circuit region and the first well region of the second array control circuit region are integrated.

### CROSS REFERENCE TO RELATED APPLICATION(S)

This application claims the benefit under 35 U.S.C. § 119 of the earlier filing date of U.S. Provisional Application Ser. No. 63/578,242, filed Aug. 23, 2023, the entire contents of which are hereby incorporated by reference in its entirety for any purpose.

### BACKGROUND

There is a case where a semiconductor memory device such as a DRAM (Dynamic Random Access Memory) includes an array control circuit that controls sense amplifiers. Since the array control circuit is required for each of sense amplifier regions arranged in an extending direction of a bit line in a multiple manner, if the length of the bit line is shortened, the arrangement pitch of array control circuits also needs to be shortened.

### BRIEF DESCRIPTION OF THE DRAWINGS

FIG. 1 is a schematic plan view showing a configuration of main parts of a semiconductor memory device according to an embodiment of the present disclosure;

FIG. 2 and FIG. 3 are schematic diagrams showing memory mats belonging to a unit U2 and various regions associated with the memory mats in an enlarged manner;

FIG. 4 is a schematic diagram for explaining circuits arranged in sub word driver regions and sense amplifier regions;

FIG. 5 is a circuit diagram of a sense amplifier;

FIG. 6 is a schematic plan view for explaining layouts of array control circuit regions;

FIG. 7 is a schematic cross-sectional view along a line A-A shown in FIG. 6;

FIG. 8 is a schematic plan view for explaining layouts of array control circuit regions according to a modification; and

FIG. 9 is a schematic plan view showing a configuration of main parts of a semiconductor memory device according to the modification.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

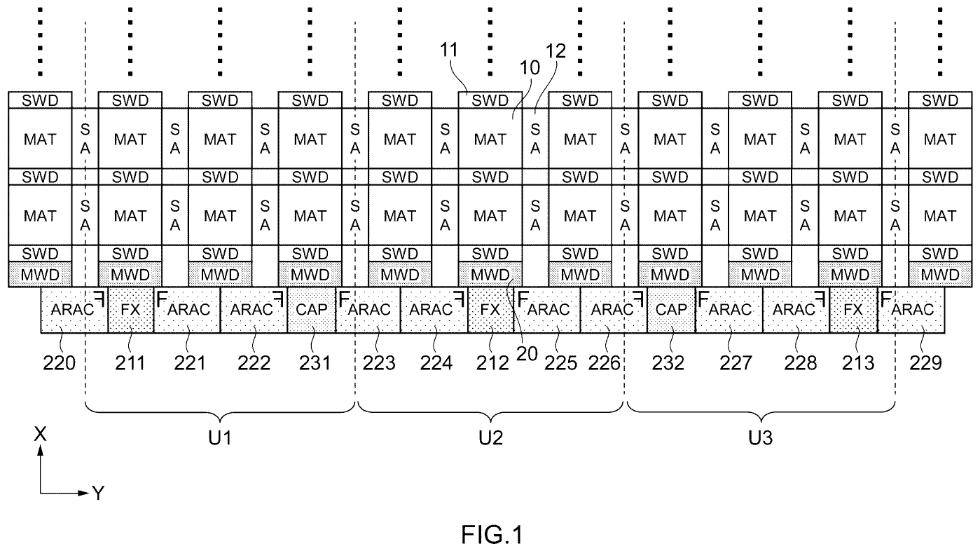

FIG. 1 is a schematic plan view showing a configuration of main parts of a semiconductor memory device according to an embodiment of the present disclosure. The semiconductor memory device shown in FIG. 1 is a DRAM and has a plurality of memory mats 10 arranged thereon in an array manner. Sub word driver regions 11 are arranged on both sides of each of the memory mats 10 in an X direction. Sense amplifier regions 12 are arranged on both sides of each of the memory mats 10 in a Y direction. The X direction and the Y direction may be perpendicular to each other. Main word driver regions 20 are arranged at ends of a plurality of memory mats 10 arrayed in the X direction. The plurality of main word driver regions 20 are arrayed in the Y direction. At the X direction side of the main word driver regions 20, a plurality of word control circuit regions 211 to 213, a plurality of array control circuit regions 220 to 229, and a plurality of compensation regions 231 and 232 are arranged.

In the present embodiment, nine memory mats 10 arrayed in the Y direction constitute three units U1 to U3. Each of the units U1 to U3 includes three memory mats 10 arrayed in the Y direction.

The word control circuit regions 211 to 213 are respectively assigned to each memory mat 10 belonging to the units U1 to U3. The word control circuit region 211 assigned to the unit U1 overlaps the memory mat 10 on the left among three corresponding memory mats 10 in the Y direction. The word control circuit region 212 assigned to the unit U2 overlaps the memory mat 10 in the center among three corresponding memory mats 10 in the Y direction. The word control circuit region 213 assigned to the unit U3 overlaps the memory mat 10 on the right among three corresponding memory mats 10 in the Y direction. The array control circuit regions 220 to 229 are respectively assigned to the sense amplifier regions 12 having positions thereof overlapping in the Y direction. A compensation capacitor that stabilizes power supply potentials is arranged in each of the compensation regions 231 and 232. A buffer circuit and the like may be also arranged in each of the compensation regions 231 and 232. In the example shown in FIG. 1, the compensation regions 231 and 232 are provided in the units U1 and U3, respectively. Any compensation region is not provided in the unit U2.

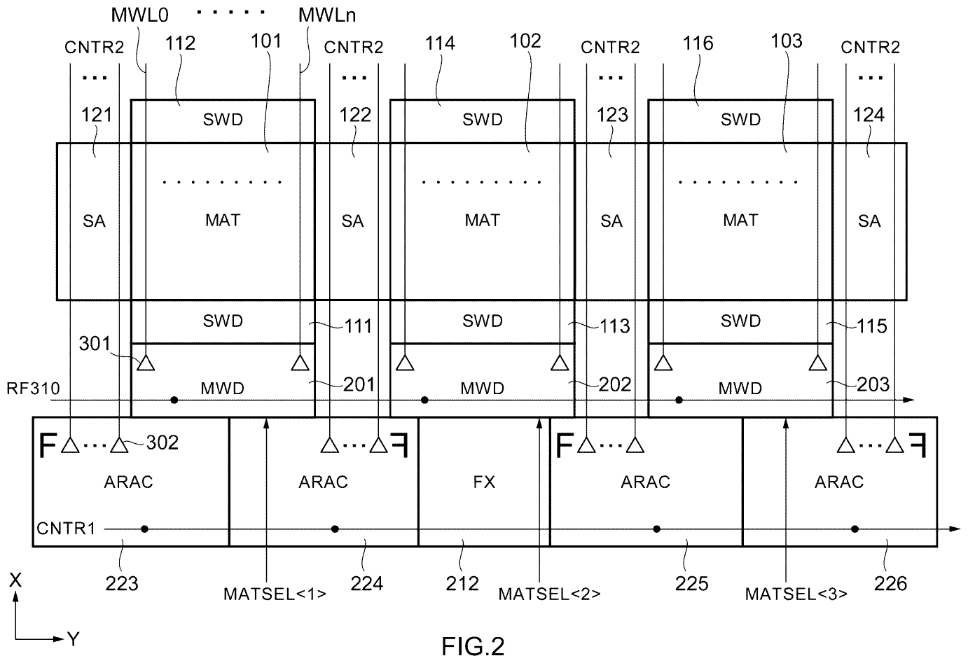

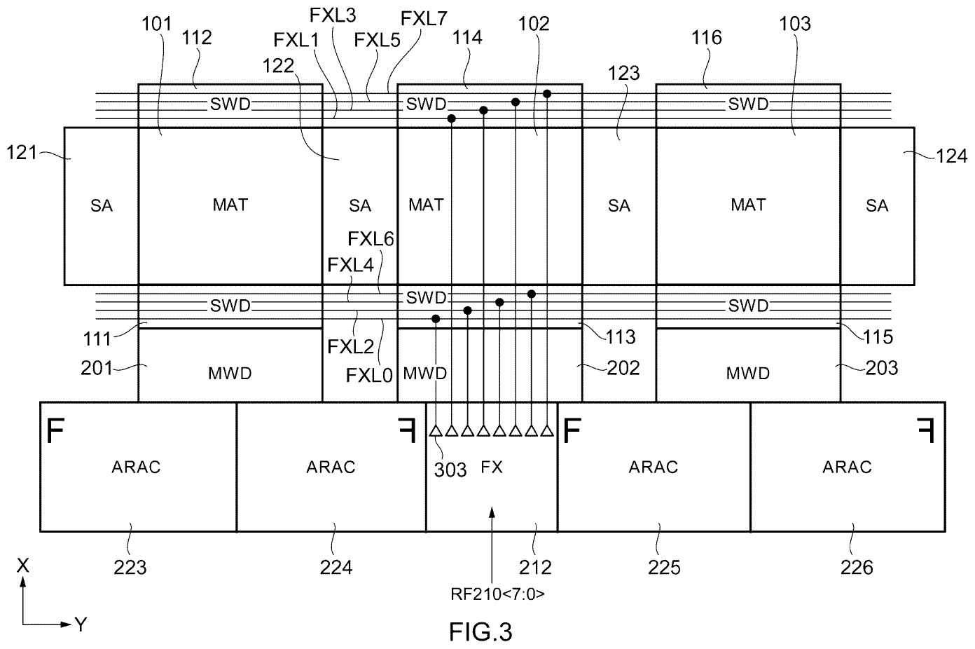

FIGS. 2 and 3 are schematic diagrams showing memory mats belonging to the unit U2 and various regions associated with the memory mats in an enlarged manner. Three memory mats 101 to 103 arrayed in the Y direction are shown in FIGS. 2 and 3. Sub word driver regions 111 and 112 are arranged on both sides of the memory mat 101 in the X direction. Sub word driver regions 113 and 114 are arranged on both sides of the memory mat 102 in the X direction. Sub word driver regions 115 and 116 are arranged on both sides of the memory mat 103 in the X direction. Sense amplifier regions 121 and 122 are arranged on both sides of the memory mat 101 in the Y direction. Sense amplifier regions 122 and 123 are arranged on both sides of the memory mat 102 in the Y direction. Sense amplifier regions 123 and 124 are arranged on both sides of the memory mat 103 in the Y direction.

Main word driver regions 201 to 203 are assigned to the memory mats 101 to 103, respectively. As shown in FIG. 2, a plurality of main word drivers 301 are arranged in each of the main word driver regions 201 to 203. The main word driver regions 201 to 203 are selected based on a pre-decode signal MATSEL generated based on a plurality of row address bits (5 bits formed of XADD11 to XADD15, for example). In the example shown in FIG. 2, when a pre-decode signal MATSEL<1> is activated, a main word driver 301 included in the main word driver region 201 is selected. When a pre-decode signal MATSEL<2> is activated, a main word driver 301 included in the main word driver region 202 is selected. When a pre-decode signal MATSEL<3> is activated, a main word driver 301 included in the main word driver region 203 is selected. Further, a pre-decode signal RF310 generated based on a plurality of other row address bits (8 bits formed of XADD3 to XADD10, for example) is commonly supplied to the main word driver regions 201 to 203.

Subsequently, one main word driver 301 selected by the pre-decode signal RF310 from a plurality of main word drivers 301 selected based on the pre-decode signal MATSEL activates any one of corresponding main word lines MWL0 to MWLn.

Array control circuit regions 223 to 226 are assigned to the sense amplifier regions 121 to 124, respectively. As shown in FIG. 2, a control signal CNTR1 is commonly supplied to the array control circuit regions 223 to 226. A plurality of array control circuits 302 included in each of the array control circuit regions 223 to 226 generate a control signal CNTR2 based on the control signal CNTR1 to supply the control signal CNTR2 to corresponding ones of the sense amplifier regions 121 to 124.

The word control circuit region 212 is commonly assigned to the memory mats 101 to 103 belonging to the unit U2. As shown in FIG. 3, eight FX driver circuits 303 are arranged in the word control circuit region 212. A pre-decode signal RF210<7:0> generated based on a plurality of other row address bits (3 bits formed of XADD0 to XADD2, for example) is commonly supplied to the word control circuit region 212. Subsequently, one FX driver circuit 303 selected by the pre-decode signal RF210<7:0> activates any one of corresponding FX signal lines FXL0 to FXL7. The FX signal lines FXL0 to FXL7 may be complementary signal lines. In the example shown in FIG. 3, the FX signal lines FXL0, FXL2, FXL4, and FXL6 extend in the X direction so as to cross the sub word driver regions 111, 113, and 115, and the FX signal lines FXL1, FXL3, FXL5, and FXL7 extend in the X direction so as to cross the sub word driver regions 112, 114, and 116.

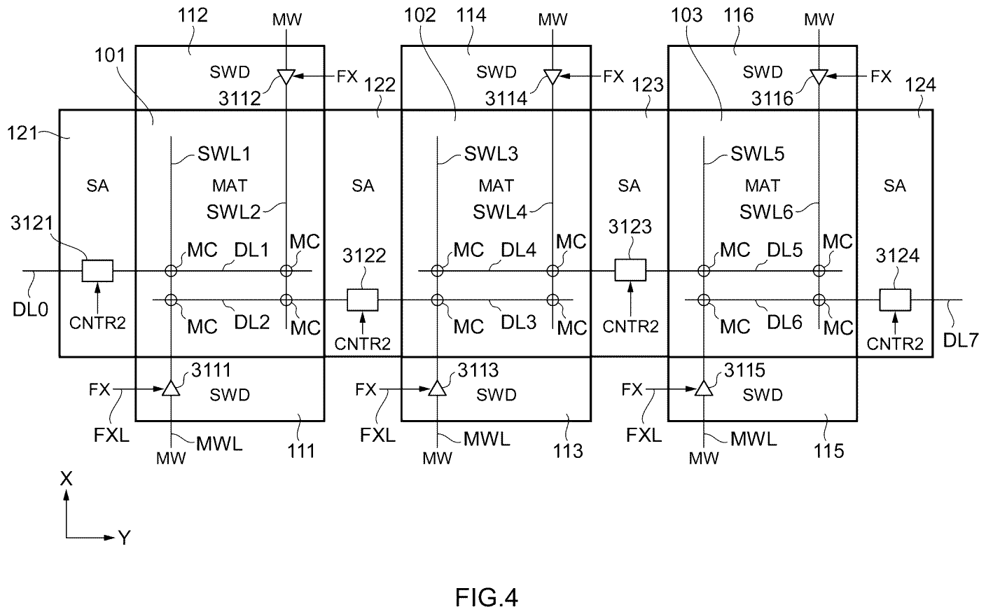

FIG. 4 is a schematic diagram for explaining circuits arranged in the sub word driver regions 111 to 116 and the sense amplifier regions 121 to 124. As shown in FIG. 4, sub word drivers 3111 to 3116 are arranged in the sub word driver regions 111 to 116, respectively. Sense amplifiers 3121 to 3124 are arranged in the sense amplifier regions 121 to 124, respectively. The sub word drivers 3111 to 3116 are coupled to a corresponding main word line MWL and a corresponding FX signal line FXL, and when a corresponding main word signal MW and a corresponding word control signal FX are activated, the sub word drivers 3111 to 3116 drive corresponding sub word lines SWL1 to SWL6, respectively. The sub word lines SWL1 and SWL2 extend in the memory mat 101 in the X direction. The sub word lines SWL3 and SWL4 extend in the memory mat 102 in the X direction.

The sub word lines SWL5 and SWL6 extend in the memory mat 103 in the X direction. The sense amplifier 3121 is coupled to a pair of digit lines DL0 and DL1. The sense amplifier 3122 is coupled to a pair of digit lines DL2 and DL3. The sense amplifier 3123 is coupled to a pair of digit lines DL4 and DL5. The sense amplifier 3124 is coupled to a pair of digit lines DL6 and DL7. Each of the sense amplifiers 3121 to 3124 amplifies a potential difference that appears on a pair of digit lines DL in response to the control signal CNTR2. The digit lines DL1 and DL2 extend in the memory mat 101 in the Y direction. The digit lines DL3 and DL4 extend in the memory mat 102 in the Y direction. The digit lines DL5 and DL6 extend in the memory mat 103 in the Y direction. A memory cell MC is arranged at each intersection between the sub word line SWL1 and the digit line DL1 and between the sub word line SWL2 and the digit line DL2. A memory cell MC is also arranged at each intersection between the sub word line SWL3 and the digit line DL3 and between the sub word line SWL4 and the digit line DL4. A memory cell MC is also arranged at each intersection between the sub word line SWL5 and the digit line DL5 and between the sub word line SWL6 and the digit line DL6.

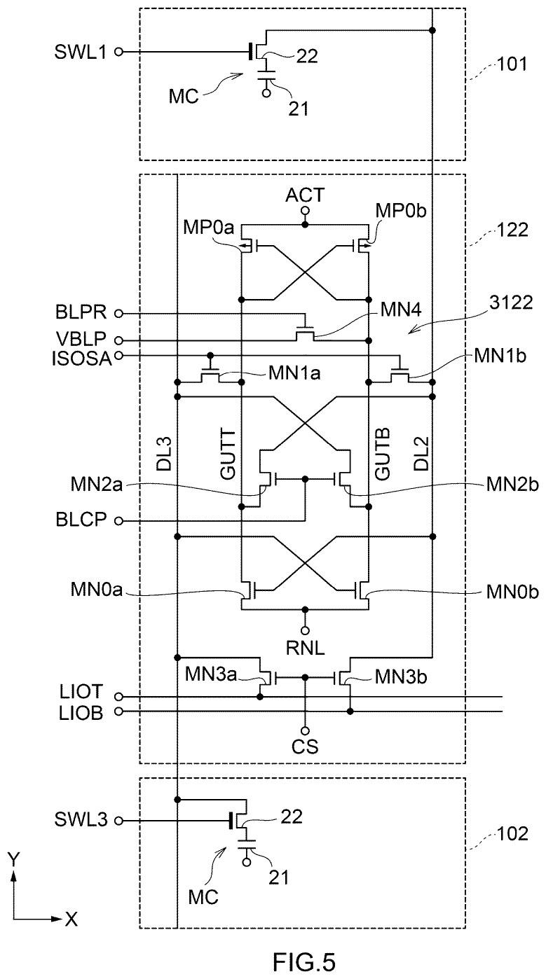

FIG. 5 is a circuit diagram of the sense amplifier 3122. As shown in FIG. 5, the sense amplifier 3122 includes cross-coupled N-channel MOS transistors MNOa and MNOb and cross-coupled P-channel MOS transistors MPOa and MPOb. A source potential RNL is supplied to respective sources of the transistors MNOa and MNOb and a source potential ACT is supplied to respective sources of the transistors MPOa and MPOb. A gate electrode of the transistor MNOa is coupled to the digit line DL2 and a gate electrode of the transistor MNOb is coupled to the digit line DL3. A drain of the transistor MNOa is coupled to an internal line GUTT and a drain of the transistor MNOb is coupled to an internal line GUTB. The internal line GUTT is coupled to a drain of the transistor MPOa and a gate electrode of the transistor MPOb and is also coupled to the digit line DL3 via an N-channel MOS transistor MN1a. The internal line GUTB is coupled to a drain of the transistor MPOb and a gate electrode of the transistor MPOa and is also coupled to the digit line DL2 via an N-channel MOS transistor MNlb. A control signal ISOSA is commonly supplied to respective gate electrodes of the transistors MN1a and MN1b. With this configuration, when the source potential RNL is driven to be a low level and the source potential ACT is driven to be a high level in a state where the control signal ISOSA is activated at a high level, a potential difference being generated between the digit lines DL2 and DL3 is amplified by the sense amplifier 3122. A memory cell MC formed of a cell capacitor 21 and a cell transistor 22 is coupled to the digit lines DL2 and DL3, and when any of the sub word lines SWL is selected based on a row address XADD, a potential difference is generated between the digit lines DL2 and DL3. Subsequently, when a column switch formed of N-channel MOS transistors MN3a and MN3b is turned on by activating a column selection signal CS based on a column address YADD, a pair of digit lines DL2 and DL3 is coupled to a pair of local I/O lines LIOT and LIOB.

The sense amplifier 3122 further includes N-channel MOS transistors MN2a and MN2b. The transistor MN2a is coupled between the internal line GUTT and the digit line DL2. The transistor MN2b is coupled between the internal line GUTB and the digit line DL3. A control signal BLCP is commonly supplied to respective gate electrodes of the transistors MN2a and MN2b. The transistors MN2a and MN2b constitute a compensation circuit that compensates a difference between respective threshold voltages of the transistors MNOa and MNOb. The sense amplifier 3122 further includes an N-channel MOS transistor MN4. A control signal BLPR is supplied to a gate electrode of the transistor MN4. When the control signal BLPR is activated to be a high level, an array potential VBLP is supplied to the internal line GUTB. The array potential VBLP corresponds to an intermediate potential between the source potential ACT and the source potential RNL.

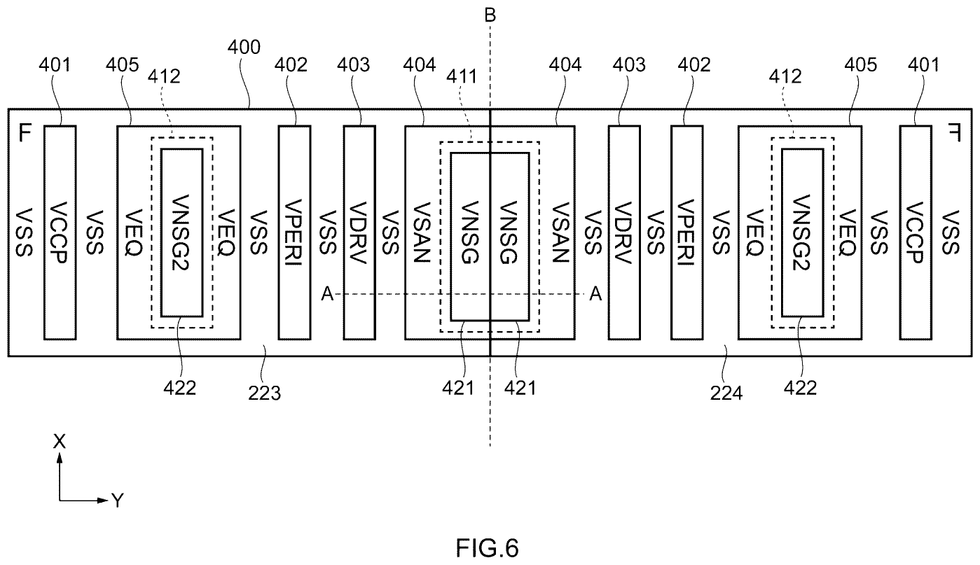

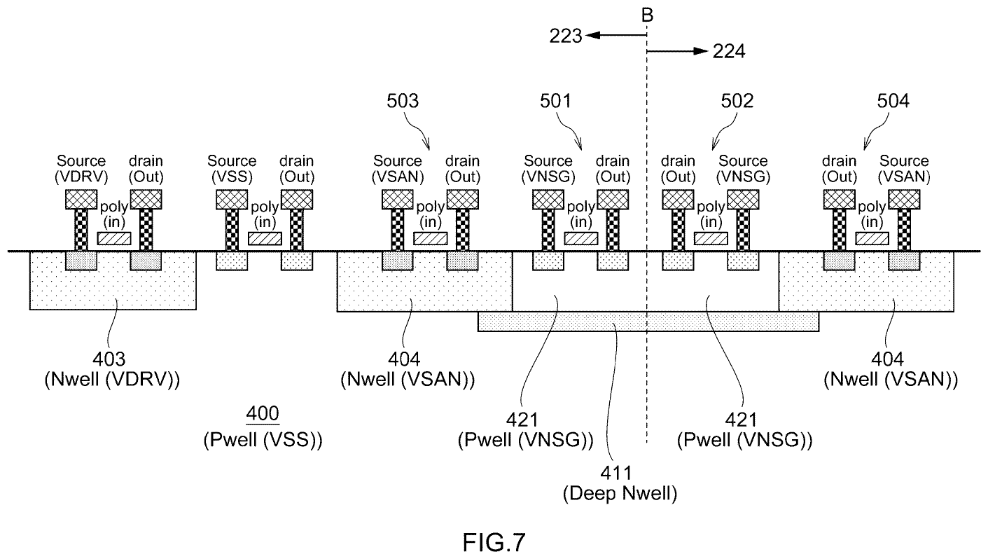

FIG. 6 is a schematic plan view for explaining layouts of the array control circuit regions 223 and 224. FIG. 7 is a schematic cross-sectional view along a line A-A shown in FIG. 6. As shown in FIG. 6, the layout of the array control circuit region 223 and that of the array control circuit region 224 are line-symmetric to each other in the Y direction with a boundary B between both regions extending in the X direction as a symmetric axis. In FIG. 6, the sign “F” denoted in the array control circuit region 223 and the sign “4 (reversed F)” denoted in the array control circuit region 224 indicate that the layouts of the array control circuit regions 223 and 224 are line-symmetric to each other. As shown in FIG. 1, the array control circuit regions 221, 223, 225, 227, and 229 denoted with “F” and the array control circuit regions 220, 222, 224, 226, and 228 denoted with “4” are arranged alternately. Therefore, for example, the layouts of the array control circuit regions 224 and 225 adjacent to each other via the word control circuit region 212 are also line-symmetric to each other.

As shown in FIG. 6, the array control circuit region 223 includes a P-well region 400 as a silicon substrate, N-well regions 401 to 405 formed in the P-well region 400, and P-well regions 421 and 422 respectively surrounded by the N-well regions 404 and 405. An N-channel MOS transistor having a source potential VSS (0V) is arranged in the P-well region 400. P-channel MOS transistors respectively having source potentials VCCP, VPERI, VDRV, VSAN, and VEQ are arranged in the N-well regions 401 to 405, respectively. Potentials of the power supplies VCCP, VPERI, VDRV, VSAN, and VEQ are mutually different from one another. N-channel MOS transistors respectively having source potentials VNSG and VNSG2 are arranged in the P-well regions 421 and 422, respectively. Potentials of the power supplies VNSG and VNSG2 are mutually different from each other. Each of the potentials of the power supplies VNSG and VNSG2 may be a negative potential different from that of the power supply VSS. Such a negative potential is used for the source potential RNL, the control signal BLCP, the control signal BLPR, and the like shown in FIG. 5. Since the potentials of the P-well regions 421 and 422 are different from the potential of the P-well region 400 as a silicon substrate, the P-well regions 421 and 422 need to be isolated from the P-well region 400. Therefore, deep N-well regions 411 and 412 are provided at positions respectively overlapping the P-well regions 421 and 422 in a plan view. That is, the P-well region 421 is isolated from the P-well region 400 by the N-well region 404 and the deep N-well region 411, and the P-well region 422 is isolated from the P-well region 400 by the N-well region 405 and the deep N-well region 412.

The array control circuit region 224 also has a layout same as that of the array control circuit region 223 except for the layout being mirror-reversed. For example, as shown in FIG. 7, a circuit 501 arranged in the P-well region 421 in the array control circuit region 223 and a circuit 502 arranged in the P-well region 421 in the array control circuit region 224 are line-symmetric to each other in the Y direction with the boundary B as a symmetric axis. As for the N-channel MOS transistor constituting each of the circuits 501 and 502, an input signal is input to a gate electrode made of polysilicon, an output signal is output from a drain, and a source is coupled to the power supply VNSG. Further, a circuit 503 arranged in the N-well region 404 in the array control circuit region 223 and a circuit 504 arranged in the N-well region 404 in the array control circuit region 224 are line-symmetric to each other in the Y direction with the boundary B as a symmetric axis. As for the P-channel MOS transistors constituting each of the circuits 503 and 504, an input signal is input to a gate electrode made of polysilicon, an output signal is output from a drain, and a source is coupled to the power supply VSAN. It is not essential to arrange a transistor in the N-well region 404 in the array control circuit regions 223 and 224, and the N-well region 404 may be used solely to isolate the P-well region 421 from the P-well region 400.

In the present embodiment, the P-well region 421 included in the array control circuit region 223 and the P-well region 421 included in the array control circuit region 224 are integrated with each other. That is, the N-well region 404 included in the array control circuit region 223 and the N-well region 404 included in the array control circuit region 224 are also integrated with each other in a ring-shape in a plan view, and an integrated P-well region 421 is arranged so as to be surrounded by the ring-shaped N-well region 404. A common deep N-well region 411 is provided between the integrated P-wellregion 421 and the P-well region 400 as a silicon substrate. With this configuration, as compared to a case where the P-well region 421 is formed separately in each of the array control circuit regions 223 and 224, the number of deep N-well regions 411 provided to isolate the P-well region 421 from a substrate can be reduced. Accordingly, the area of element isolation regions required for the array control circuit regions 220 to 229 is reduced. Here, the sizes of the array control circuit regions 220 to 229 in the Y direction are substantially determined based on the size of the memory mat 10 in the Y direction. Furthermore, in the present embodiment, since the area of element isolation regions required for the array control circuit regions 220 to 229 is reduced, the sizes of the array control circuit regions 220 to 229 in the X direction can be reduced.

Further, since the word control circuit regions 211 to 213 respectively assigned to the units U1 to U3 are not arranged in each unit in a distributed manner but are arranged with one another in the same position, the wiring length of signal lines in the Y direction arranged on the word control circuit regions 211 to 213 and used to control the FX driver circuit 303 can be shortened.

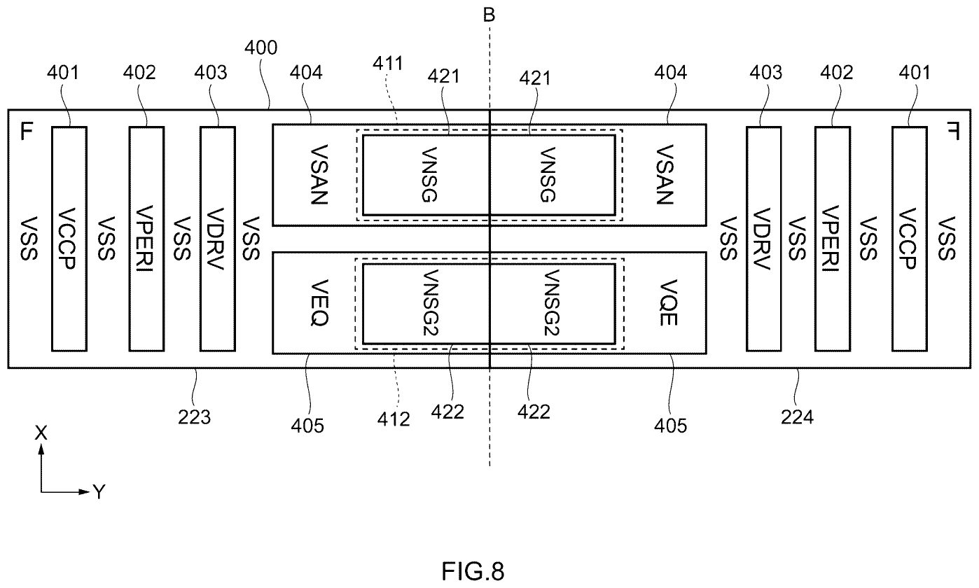

FIG. 8 is a schematic plan view for explaining layouts of the array control circuit regions 223 and 224 according to a modification. In the example shown in FIG. 8, not only P-well regions 421 but also P-well regions 422 are integrated with each other between the array control circuit regions 223 and 224. With this configuration, the area of element isolation regions required for the array control circuit regions 220 to 229 can be further reduced.

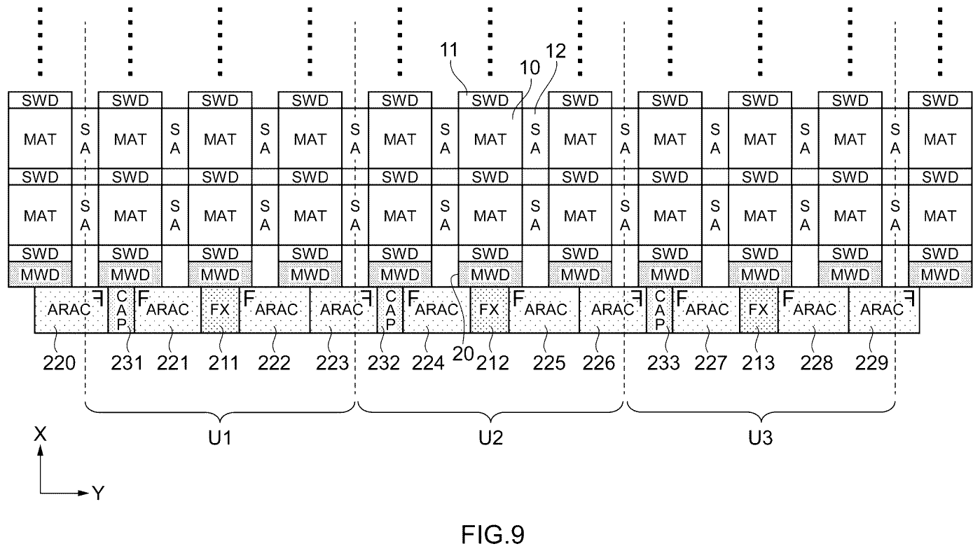

FIG. 9 is a schematic plan view showing a configuration of main parts of a semiconductor memory device according to the modification. In the example shown in FIG. 9, the layout is different from that shown in FIG. 1 such that the units U1 to U3 have mutually the same layout. That is, each of the word control circuit regions 211 to 213 respectively assigned to the units U1 to U3 overlaps the memory mat 10 in the center among three corresponding memory mats 10 in the Y direction. Among the three memory mats 10 included in each of the units U1 to U3, at a position overlapping the memory mat 10 on the left, compensation regions 231 to 233 are arranged respectively. Further, among the three memory mats 10 included in the respective units U1 to U3, two array control circuit regions arranged at positions overlapping on the memory mat 10 on the right in the Y direction are line-symmetric to each other, and as explained with reference to FIG. 6, the P-well region 421 is shared between the two array control circuit regions. That is, in the unit U1, the array control circuit regions 222 and 223 are line-symmetric to each other and the P-well region 421 is shared between these regions. In the unit U2, the array control circuit regions 225 and 226 are line-symmetric to each other and the P-well region 421 is shared between these regions. In the unit U3, the array control circuit regions 228 and 229 are line-symmetric to each other and the P-well region 421 is shared between these regions. According to such a layout, in each of the units U1 to U3, since the array control circuit regions 211 to 213 are arranged at positions overlapping the memory mat 10 in the center among the three corresponding memory mats 10 in the Y direction, there will be no difference in the lengths of FX signal lines among the units U1 to U3.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a first memory mat;
first and second sense amplifier regions arranged such that the first memory mat is sandwiched between the first and second sense amplifier regions in a first direction, the first sense amplifier region including a first sense amplifier, and the second sense amplifier region including a second sense amplifier; and
first and second array control circuit regions arranged in the first direction, the first array control circuit region including a first array control circuit configured to control the first sense amplifier, and the second array control circuit region including a second array control circuit configured to control the second sense amplifier,
wherein each of the first and second array control circuit regions includes a first well region of a first conductivity type in which a first circuit part of each of the first and second array control circuits are arranged, respectively, and
wherein the first well region of the first array control circuit region and the first well region of the second array control circuit region are integrated.

2. The apparatus of claim 1, wherein a layout of the first circuit part of the first array control circuit and a layout of the first circuit part of the second array control circuit are arranged symmetrically with respect to a boundary between the first and second array control circuit regions.

3. The apparatus of claim 1, wherein the first well regions of the first and second array control circuit regions are isolated from a semiconductor substrate of the first conductivity type.

4. The apparatus of claim 3,
wherein each of the first and second array control circuit regions further includes a second well region of a second conductivity type opposite to the first conductivity type, and
wherein the first well regions of the first and second array control circuit regions are surrounded by the second well regions of the first and second array control circuit regions in a plan view.

5. The apparatus of claim 4, wherein the first well regions of the first and second array control circuit regions overlap a third well region of the second conductivity type such that the first well regions of the first and second array control circuit regions are isolated from the semiconductor substrate by the second and third well regions.

6. The apparatus of claim 5, wherein each of the first and second array control circuits further includes a second circuit part arranged in the second well region of each of the first and second array control circuit regions, respectively.

7. The apparatus of claim 6, wherein a layout of the first and second circuit parts of the first array control circuit and a layout of the first and second circuit parts of the second array control circuit are arranged symmetrically with respect to a boundary between the first and second array control circuit regions.

8. The apparatus of claim 1, further comprising:
a third sense amplifier region including a third sense amplifier;
a second memory mat arranged between the second and third sense amplifier regions in the first direction; and
a third array control circuit region including a third array control circuit configured to control the third sense amplifier,
wherein a layout of the second array control circuit and a layout of the third array control circuit are arranged symmetrically in the first direction.

9. The apparatus of claim 8,
wherein the first memory mat includes first and second digit lines extending in the first direction,
wherein the second memory mat includes third and fourth digit lines extending in the first direction,
wherein the first sense amplifier is coupled to the first digit line,
wherein the second sense amplifier is coupled to the second and third digit lines, and
wherein the third sense amplifier is coupled to the fourth digit line.

10. The apparatus of claim 9, further comprising:
a first word driver circuit configured to activate a first word line included in the first memory mat and extending in a second direction perpendicular to the first direction;
a second word driver circuit configured to activate a second word line included in the second memory mat and extending in the second direction; and
a word control circuit configured to control the first and second word driver circuits,
wherein the word control circuit is arranged between the second and third array control circuit regions in the first direction.

11. The apparatus of claim 10, further comprising:
a fourth sense amplifier region including a fourth sense amplifier;
a third memory mat arranged between the third and fourth sense amplifier regions in the first direction; and
a fourth array control circuit region including a fourth array control circuit configured to control the fourth sense amplifier,
wherein a layout of the third array control circuit and a layout of the fourth array control circuit are arranged symmetrically in the first direction.

12. The apparatus of claim 11,
wherein each of the third and fourth array control circuit regions includes a first well region of the first conductivity type in which a first circuit part of each of the third and fourth array control circuits are arranged, respectively, and
wherein the first well region of the third array control circuit region and the first well region of the fourth array control circuit region are integrated.

13. The apparatus of claim 11, further comprising an additional circuit region arranged between the third and fourth array control circuit regions.

14. The apparatus of claim 13, wherein the additional circuit region includes a compensation capacitor.

15. An apparatus comprising:
first, second, third, and fourth sense amplifiers arranged in a first direction in this order;
a first memory mat arranged between the first and second sense amplifiers;
a second memory mat arranged between the second and third sense amplifiers;
a third memory mat arranged between the third and fourth sense amplifiers; and
first, second, third, and fourth array control circuits each configured to control the first, second, third, and fourth sense amplifiers, respectively,
wherein the first, second, third, and fourth array control circuits and the first, second, third, and fourth sense amplifiers are arranged in a second direction perpendicular to the first direction, respectively,
wherein a layout of the first array control circuit and a layout of the second array control circuit are arranged symmetrically in the first direction,
wherein a layout of the second array control circuit and a layout of the third array control circuit are arranged symmetrically in the first direction, and
wherein a layout of the third array control circuit and a layout of the fourth array control circuit are arranged symmetrically in the first direction.

16. The apparatus of claim 15,
wherein the first and second array control circuits share a first well region, and
wherein the first well region has the same conductivity type as a semiconductor substrate and is isolated from the semiconductor substrate.

17. The apparatus of claim 16,
wherein the third and fourth array control circuits share a second well region, and
wherein the second well region has the same conductivity type as the semiconductor substrate and is isolated from the semiconductor substrate.

18. The apparatus of claim 17, further comprising:
first, second, and third word driver circuits assigned to the first, second, and third memory mats, respectively; and
a word control circuit configured to control the first, second, and third word driver circuits,
wherein the word control circuit is arranged between the second and third array control circuits.

19. An apparatus comprising:
first, second, third, and fourth sense amplifiers arranged in a first direction in this order;
a first memory mat arranged between the first and second sense amplifiers;
a second memory mat arranged between the second and third sense amplifiers;
a third memory mat arranged between the third and fourth sense amplifiers;
first, second, third, and fourth array control circuits each configured to control the first, second, third, and fourth sense amplifiers, respectively;
first, second, and third word driver circuits assigned to the first, second, and third memory mats, respectively;
a word control circuit configured to control the first, second, and third word driver circuits; and
a compensation capacitor,
wherein the first, second, third, and fourth array control circuits and the first, second, third, and fourth sense amplifiers are arranged in a second direction perpendicular to the first direction, respectively,
wherein a layout of the first array control circuit and a layout of the second array control circuit are arranged symmetrically in the first direction,
wherein a layout of the third array control circuit and a layout of the fourth array control circuit are arranged symmetrically in the first direction,
wherein the word control circuit is arranged between the second and third array control circuits, and
wherein the compensation capacitor is arranged between the first and second array control circuits.

20. The apparatus of claim 19,
wherein the third and fourth array control circuits share a first well region, and
wherein the first well region has the same conductivity type as a semiconductor substrate and is isolated from the semiconductor substrate.
